(19) United States
(12) Patent Application Publication
(10) Pub. No.: US 2008/0308145 A1
(43) Pub. Date: Dec. 18, 2008

(54) Front electrode including transparent conductive coating on etched glass substrate for use in photovoltaic device and method of making same

(75) Inventors: Alexey Krasnov, Canton, MI (US); Scott V. Thomsen, South Lyon, MI (US); Yiwei Lu, Ann Arbor, MI (US)

Correspondence Address: NIXON & VANDERHYE, PC, 901 NORTH GLEBE ROAD, 11TH FLOOR, ARLINGTON, VA, 22203, US

(73) Assignee: Guardian Industries Corp, Auburn Hills, MI (US)

(21) Appl. No.: 11/808,765

(22) Filed: Jun. 12, 2007

(51) Int. Cl. H01L 31/02; C03C 15/00; H01L 31/20; C23C 14/08

(52) U.S. Cl. 136/256; 204/192.1

(57) ABSTRACT

Certain example embodiments of this invention relate to a front electrode provided on an etched/patterned front glass substrate for use in a photovoltaic device or the like. The glass is a low-iron soda-lime-silica based glass. Etching of the glass may include immersing the soda-lime-silica based glass in an acid inclusive solution such as hydrofluoric acid (e.g., HF in aqueous solution) and/or hydrofluoric acid with a buffer, in order to selectively dissolve some of the glass thereby producing at least one textured/patterned substantially transparent surface of the glass substrate. A front electrode (single or multi-layered) is then formed (e.g., via sputter-deposition) on the textured surface of the front glass substrate, and may be used in a photovoltaic device or the like.

This invention relates to a photovoltaic device including an electrode such as a front electrode/contact provided on an etched front glass substrate. In certain example embodiments, the front electrode of the photovoltaic device includes a conformal transparent conductive coating (single or multi-layered) which is sputter-deposited on a textured surface of the etched/patterned glass substrate. In certain example instances, this is advantageous in that efficiency of the photovoltaic device can be improved by increasing light absorption by the active semiconductor via both increasing light intensity passing through the front glass substrate and front electrode, and increasing the light path in the semiconductor photovoltaic conversion layer.

### BACKGROUND AND SUMMARY OF EXAMPLE EMBODIMENTS OF INVENTION

Photovoltaic devices are known in the art (e.g., see U.S. Pat. Nos. 6,784,361, 6,288,325, 6,613,603, and 6,123,824, the disclosures of which are hereby incorporated herein by reference). Amorphous silicon (a-Si) photovoltaic devices, for example, include a front electrode or contact. Typically, the transparent front electrode is made of a pyrolytic transparent conductive oxide (TCO) such as zinc oxide or tin oxide formed on a substrate such as a glass substrate. Thin film amorphous silicon solar cells are gaining in popularity due to savings in semiconductor material and thus cost; less than 1 μm of Si thickness compared to about 250 μm or so of Si thickness in conventional single crystal Si solar cells. The small thickness of the semiconductor absorber in a-Si solar cells, however, allows a substantial amount of solar light to pass through the absorber without producing electron-hole pairs, thereby lowering the efficiency of the photovoltaic device. There are several ways to increase efficiency of an a-Si solar cell, including roughening of the front electrode. Moreover, higher solar light transmission and higher conductivity of the front electrode may result in higher device efficiency.

In many instances, the transparent front electrode is formed of a single layer using a method of chemical pyrolysis where precursors are sprayed onto the glass substrate at approximately 400 to 600 degrees C. Typical pyrolitic fluorine-doped tin oxide TCOs as front electrodes may be about 400-800 nm thick, which provides for a sheet resistance (Rₛ) of about 7-15 ohms/square. It is known to increase the light path in thin film photovoltaic devices by etching/patterning a surface of a sputtered TCO front electrode after it has been deposited on the front glass substrate. It is also known to deposit some types of TCO on a flat glass substrate in a high process pressure environment in order to cause texturing of the TCO front electrode via column structure growth in the TCO. Unfortunately, both of these techniques often compromise the electrical properties of the TCO front electrode of the photovoltaic device and/or result in an increased thickness of the pre-etched TCO.

Moreover, it is possible to sputter-deposit a zinc aluminum oxide TCO on a glass substrate, and to then etch the surface of the zinc aluminum oxide TCO to be used as the front electrode. However, to achieve a textured sputtered zinc aluminum oxide front electrode, a thicker TCO is needed because the etching of the TCO removes a significant part of the thickness of the material. This removal of a significant part of the TCO thickness is wasteful and results in higher overall costs of the coating.

In view of the above, it will be appreciated that there exists a need in the art for an improved front electrode structure, and/or method of making the same, for use in a photovoltaic device or the like.

Certain example embodiments of this invention relate to a front electrode provided on an etched/patterned front glass substrate for use in a photovoltaic device or the like. The glass is a low-iron soda-lime-silica based glass in certain example embodiments. In certain example embodiments, the etching may comprise immersing the soda-lime-silica based glass in an acid inclusive solution such as hydrofluoric acid (e.g., HF in aqueous solution) and/or hydrofluoric acid with a buffer, such as BaSO₄ of the like, in order to selectively dissolve some of the glass thereby producing at least one textured/patterned substantially transparent surface of the glass substrate.

It has surprisingly been found that in order to achieve good haze properties, the etching ratio of the glass composition, namely (Al₂O₃/Na₂O)×(MgO/CaO) in the glass, has to be at least about 0.030, and more preferably at least about 0.035. Moreover, it has also surprisingly been found that in order to achieve good haze properties, the ratio MgO/CaO in the glass has to be at least about 0.45, more preferably at least about 0.47. These values have unexpectedly been found to provide for much better haze values compared to if these values are not met.

In certain example embodiments of this invention, the average roughness at the textured surface of the front glass substrate is from about 0.010 to 1000 μm, more preferably from about 1 to 500 μm, and most preferably from about 1 to 200 μm.

In certain example embodiments of this invention, a transparent conductive coating (e.g., TCO comprising zinc oxide and/or zinc aluminum oxide) is sputter-deposited on the etched and thus textured surface of a glass substrate in order to form a front electrode structure. The use of sputter-deposition to form the conductive electrode is advantageous in that it permits the electrode (single or multi-layered) to be deposited in a conformal manner so that both major surfaces of the electrode are shaped in a manner similar to that of the etched/textured surface of the glass substrate on which the electrode has been deposited. Thus, the surface of the front electrode closest to the semiconductor absorber film of the photovoltaic device is also textured. In certain example embodiments, there is no need to etch the surface of the front electrode after it has been deposited.

Certain example embodiments of this invention are advantageous in that efficiency of the photovoltaic device can be improved by (a) increasing the solar light trapping within the semiconductor absorber due to the textured surface(s) of both the front electrode and front glass substrate, and (b) increasing the light path in the semiconductor absorber (or photovoltaic conversion layer) due t-o light scattering at larger angles, while at the same time maintaining good electrical properties of the front electrode.

The front electrode may be a single-layer of a transparent conductive oxide (TCO) in certain example embodiments of this invention. In other example embodiments, the front electrode may be made up of multiple layers; one or more of which may be conductive. Because sputtered thin films may be conformal t the patterned glass substrate, multiple layered thin films with controlled thickness and optical properties may be fabricated one layer after another to enhance the transmission of light into the semiconductor absorber film through optical interference, and the increased light path through the scattering inherited from the patterned glass may be preserved in certain example embodiments.

In certain example embodiments of this invention, there is provided a method of making a photovoltaic device, the method comprising: providing a soda-lime-silica based glass substrate which comprises from about 67-75% SiO₂, from about 10-20% Na₂O, from about 5-15% CaO, from about 0.1 to 8% MgO, and from about 0.1 to 5% Al₂O₃; etching at least one major surface of the glass substrate to form a textured surface of the glass substrate, wherein (a) an etching ratio ((Al₂O₃/Na₂O)*(MgO/CaO)) of the glass substrate is at least about 0.010, and/or (b) a ratio MgO/CaO in the glass substrate is at least about 0.45; sputter-depositing a substantially transparent and electrically conductive front electrode on the textured surface of the glass substrate; and using the front electrode formed on the textured surface of the glass substrate at a light incident side of a photovoltaic device.

In other example embodiments, there is provided a method of making a photovoltaic device, the method comprising: providing a soda-lime-silica based glass substrate which comprises from about 67-75% SiO₂, from about 10-20% Na₂O, from about 5-15% CaO, from about 0.1 to 8% MgO, and from about 0.1 to 5% Al₂O₃; etching at least one major surface of the glass substrate to form a textured surface of the glass substrate, wherein an etching ratio ((Al₂O₃/Na₂O)*(MgO/CaO)) of the glass substrate is at least about 0.010, and a ratio MgO/CaO in the glass substrate is at least about 0.45; sputter-depositing a substantially transparent and electrically conductive front electrode on the textured surface of the glass substrate; and using the front electrode formed on the textured surface of the glass substrate at a light incident side of a photovoltaic device.

In other example embodiments, there is provided a photovoltaic device comprising: a soda-lime-silica based front glass substrate which comprises from about 67-75% SiO₂, from about 10-20% Na₂O, from about 5-15% CaO, from about 0.1 to 8% MgO, and from about 0.1 to 5% Al₂O₃; a semiconductor film; a substantially transparent conductive front electrode provided between at least the front glass substrate and the semiconductor film; and wherein a ratio ((Al₂O₃/Na₂O)* (MgO/CaO)) of a composition of the glass substrate is at least about 0.010 (more preferably at least about 0.30 or 0.35), and a ratio MgO/CaO of the composition of the glass substrate is at least about 0.45 (more preferably at least about 0.47).

### BRIEF DESCRIPTION OF THE DRAWINGS

FIG. 1 is a cross sectional view of an example photovoltaic device according to an example embodiment of this invention.

FIG. 2 is a visible transmission (%) into semiconductor film versus wavelength (nm) graph, illustrating characteristics of an example a-Si photovoltaic device regarding quantum efficiency (QE), a multi-layered front electrode structure, and air mass 1.5 (AM1.5), according to an example embodiment (Example 1) of this invention.

FIG. 3 is a visible transmission (%) into semiconductor film versus wavelength (nm) graph, illustrating characteristics of an example a-Si photovoltaic device regarding quantum efficiency (QE), a multi-layered front electrode structure, and air mass 1.5 (AM1.5), according to another example embodiment (Example 2) of this invention.

FIG. 4 is a visible transmission (%) into semiconductor film versus wavelength (nm) graph, illustrating characteristics of an example CdTe photovoltaic device regarding quantum efficiency (QE), a multi-layered front electrode structure, and air mass 1.5 (AM1.5), according to yet another example embodiment of this invention.

FIG. 5 is a flowchart illustrating example steps in making a photovoltaic device, and front electrode structure therefor, according to an example embodiment of this invention; these steps may be performed in connection with any embodiment of this invention.

FIG. 6 is a cross sectional view of an example photovoltaic device according to another example embodiment of this invention (note: the textured surfaces of the front glass substrate and front electrode are not shown in this figure for purposes of simplicity).

### DETAILED DESCRIPTION OF EXAMPLE EMBODIMENTS OF THE INVENTION

Referring now more particularly to the figures in which like reference numerals refer to like parts/layers in the several views.

Photovoltaic devices such as solar cells convert solar radiation into usable electrical energy. The energy conversion occurs typically as the result of the photovoltaic effect. Solar radiation (e.g., sunlight) impinging on a photovoltaic device and absorbed by an active region of semiconductor material (e.g., a semiconductor film including one or more semiconductor layers such as a-Si layers, the semiconductor sometimes being called an absorbing layer or film) generates electron-hole pairs in the active region. The electrons and holes may be separated by an electric field of a junction in the photovoltaic device. The separation of the electrons and holes by the junction results in the generation of an electric current and voltage. In certain example embodiments, the electrons flow toward the region of the semiconductor material having n-type conductivity, and holes flow toward the region of the semiconductor having p-type conductivity. Current can flow through an external circuit connecting the n-type region to the p-type region as light continues to generate electron-hole pairs in the photovoltaic device.

In certain example embodiments, single junction amorphous silicon (a-Si) photovoltaic devices have a semiconductor film which includes three semiconductor layers. In particular, a p-layer, an n-layer and an i-layer which is intrinsic. The amorphous silicon film (which may include one or more layers such as p, n and i type layers) may be of hydrogenated amorphous silicon in certain instances, but may also be of or include hydrogenated amorphous silicon carbon or hydrogenated amorphous silicon germanium, or the like, in certain example embodiments of this invention. For example and without limitation, when a photon of light is absorbed in the i-layer it gives rise to a unit of electrical current (an electron-hole pair). The p and n-layers, which contain charged dopant ions, set up an electric field across the i-layer which draws the electric charge out of the i-layer and sends it to an optional external circuit where it can provide power for electrical components. It is noted that while certain example embodiments of this invention are directed toward amorphous-silicon based photovoltaic devices (e.g., single-junction or micromorph types), this invention is not so limited and may be used in conjunction with other types of photovoltaic devices in certain instances including but not limited to devices including other types of semiconductor material, single or tandem thin-film solar cells, CdS and/or CdTe photovoltaic devices, polysilicon and/or microcrystalline Si photovoltaic devices, and the like.

Referring generally to the figures, certain example embodiments of this invention relate to a front electrode 3 provided on an etched/patterned front glass substrate 1 for use in a photovoltaic device or the like. The glass 1 of the front glass substrate is a low-iron soda-lime-silica based glass in certain example embodiments. In certain example embodiments, the etching of glass 1 in order to form the textured (or patterned) surface on the front glass substrate may comprise protecting what is to be exterior or light-incident surface of the glass substrate and immersing the soda-lime-silica based glass in an acid inclusive solution such as hydrofluoric acid (e.g., HF in aqueous solution) and/or hydrofluoric acid with a buffer, such as BaSO₄ of the like, in order to selectively dissolve some of the glass on what is to be the interior surface of the glass substrate 1 thereby producing at least one textured/patterned substantially transparent surface 1a of the glass substrate. The textured surface 1a of the front glass substrate 1 results in the front electrode 3 which is formed thereon also having first and/or second textured surfaces.

The textured surface of the front electrode 3 is characterized by both haze and angular dependence of the transmitted (reflected) light. Haze is the ratio between the diffused part of the transmitted (reflected) light and the total amount of the transmitted (reflected) light. Haze increases with increasing surface roughness. If the front electrode 3 is of a TCO such as ZnAlOₓ for instance, and if haze is determined by the size of ZnAlOₓ grains however, the increase in the grain size can result in the scattering of the transmitted light into smaller angles around the specular direction. Thus, an increase in haze solely by way of growing thicker and more textured ZnAlOₓ has limitations.

It has surprisingly been found that in order to achieve good haze properties of the front electrode 3, the glass 1 has to be etched in a given manner. In particular, the etching ratio of the glass composition of substrate 1, namely (Al₂O₃/Na₂O)×(MgO/CaO) in the glass, has to be at least about 0.010, more preferably at least about 0.030, and more preferably at least about 0.035. Moreover, it has also surprisingly been found that in order to achieve good haze properties, the ratio MgO/CaO in the glass 1 has to be at least about 0.45, more preferably at least about 0.47. These values have unexpectedly been found to provide for much better haze values of the front electrode 3 which is deposited on the textured surface, compared to if these values are not met.

In certain example embodiments of this invention, a transparent conductive coating (e.g., TCO comprising zinc oxide and/or zinc aluminum oxide) 3 is sputter-deposited on the etched and thus textured surface of the front glass substrate 1 in order to form a front electrode structure. The use of sputter-deposition to form the conductive electrode 3 is advantageous in that it permits the electrode (single or multi-layered) to be deposited in a conformal manner so that both major surfaces of the electrode may be shaped in a manner similar to that of the interior etched/textured surface 1 a of the glass substrate 1 on which the electrode 3 has been deposited. Thus, the surface of the front electrode 3 closest to the semiconductor absorber film 5 of the photovoltaic device is also textured. In certain example embodiments, there is no need to etch the surface of the front electrode 3 after it has been deposited.

The front electrode 3 may be a single-layer of TCO such as ZnAlOₓ or the like in certain example embodiments of this invention. In certain example embodiments, such a front electrode 3 (e.g., of or including ZnO, and/or ZnAlOₓ) may be from about 100 to 1,000 nm thick, more preferably from about 200 to 700 nm thick. With respect to the front electrode, the ZnAlOₓ may contain from about 1-5% Al, more preferably from about 1.5 to 4% Al.

In other example embodiments, the front electrode 3 may be made up of multiple layers (e.g., see FIG. 6); one or more of which may be conductive. In certain example embodiments of this invention, referring to FIG. 6 for example, the front electrode 3 may be comprised of a multilayer coating including at least one transparent conductive oxide (TCO) layer (e.g., of or including a material such as tin oxide, zinc oxide, or the like) (3a, 3c and/or 3e) and at least one conductive substantially metallic layer (e.g., based on silver, gold, or the like) (3b and/or 3d). Such a multi-layer front electrode can be used in single-junction a-Si solar cells without significantly sacrificing their efficiency because the QE curve of these devices has a cut-off at about 750 nm corresponding to the a-Si bandgap of about 1.7 eV (e.g., see FIG. 2). In certain example instances, the multilayer front electrode coating may include a plurality of TCO layers (3a, 3c and/or 3e) and/or a plurality of conductive substantially metallic substantially transparent (to visible light) layers (3b and/or 3d) arranged in an alternating manner in order to provide for reduced visible light reflections, increased conductivity, and so forth (e.g., see FIG. 6). In certain example embodiments of this invention, the multilayer front electrode 3 coating is designed to realize one or more of the following advantageous features: (a) reduced sheet resistance (Rₛ) and thus increased conductivity and improved overall photovoltaic module output power; (b) reduced reflection and increased transmission of light in the region(s) where solar QE is significant such as from about 450-700 nm and/or 450-600 nm which leads to increased photovoltaic module output power; (c) reduced total thickness of the front electrode coating which can reduce fabrication costs and/or time; and/or (d) an improved or enlarged process window in forming the TCO layer(s) because of the reduced impact of the TCO's conductivity on the overall electric properties of the module given the presence of the highly conductive substantially metallic layer(s).

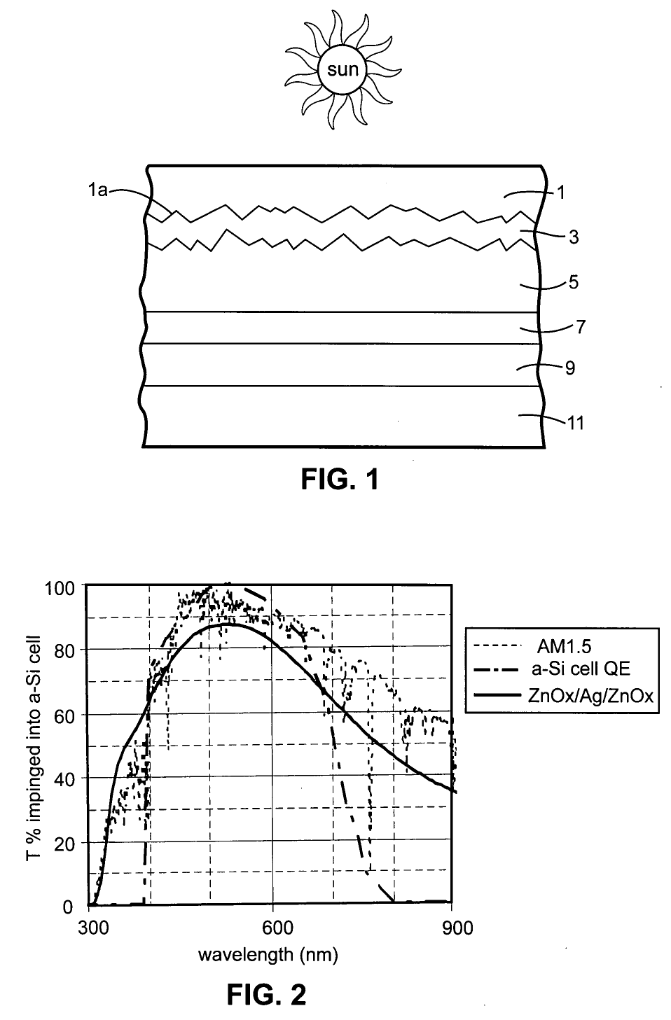

FIG. 1 is a cross sectional view of a photovoltaic device according to an example embodiment of this invention. The photovoltaic device includes transparent front glass substrate 1 having a textured surface 1a closest to the semiconductor film, front electrode 3 (which may be multi-layered or single-layered), active and absorbing semiconductor film 5 of or including one or more semiconductor layers (such as pin, pn, pinpin tandem layer stacks, or the like), optional back electrode/contact 7 which may be of a TCO and/or metal(s), an optional polymer based encapsulant or adhesive 9 of a material such as ethyl vinyl acetate (EVA) or the like, and an optional rear substrate 11 of a material such as glass. The front glass substrate 1 is on the light incident side of the photovoltaic device. Of course, other layer(s) which are not shown may also be provided in the device. Front glass substrate 1 and/or rear substrate 11 may be made of soda-lime-silica based glass in certain example embodiments of this invention; and may have low iron content and/or an antireflection coating thereon to optimize transmission in certain example instances. Glass 1 and/or 11 may or may not be thermally tempered in certain example embodiments of this invention. Additionally, it will be appreciated that the word “on” as used herein covers both a layer being directly on and indirectly on something, with other layers possibly being located therebetween. Optionally, an antireflective film (not shown) or other film may be provided on the light-incident side of the front substrate 1 in certain example instances.

In certain example embodiments of this invention, the average roughness on the etched/textured surface 1 a of the front glass substrate 1 is from about 0.010 to 1000 μm, more preferably from about 1 to 500 μm, and most preferably from about 1 to 200 μm (measured as distance between a peak and adjacent valley on the textured surface). The textured surface 1a of the glass substrate 1 may have a prismatic surface, a matte finish surface, or the like in different example embodiments of this invention. In certain example embodiments, the average peak-to-peak distance between adjacent peaks on the textured surface 1a of the glass 1 is from about 0.010 to 5,000 μm, more preferably from about 10 to 2,000 μm. Because the front electrode is deposited (e.g., sputter-deposited) on the textured surface 1a of the front substrate, one or possibly both major surfaces of the front electrode 3 are also textured in a similar manner. The textured surface 1a of the glass substrate 1, and the major surfaces of the front electrode 3, may have peaks and valleys defined therein with inclined portions interconnecting the peaks and valleys (e.g., see FIG. 1).

Front glass substrate 1 utilizes soda-lime-silica based glass in certain example embodiments. In addition to base composition/glass, a colorant portion may be provided in order to achieve a glass that is fairly clear in color and/or has a high visible transmission. An exemplary soda-lime-silica base glass according to certain embodiments of this invention, on a weight percentage basis, includes the following basic ingredients:

TABLE 1
EXAMPLE BASE GLASS

| Ingredient | Wt. % |
|---|---|
| SiO₂ | 67-75% |
| Na₂O | 10-20% |
| CaO | 5-15% |
| MgO | 0.1-8% |
| Al₂O₃ | 0.1-5% |
| K₂O | 0-5% |

In addition to the base glass (e.g., see Table 1 above), in making glass according to certain example embodiments of the instant invention the glass batch includes materials (including colorants and/or oxidizers) which cause the resulting glass to be fairly neutral in color (slightly yellow in certain example embodiments, indicated by a slightly positive b* value) and/or have a high visible light transmission. These materials may either be present in the raw materials (e.g., small amounts of iron), or may be added to the base glass materials in the batch (e.g., cerium oxide).

Moreover, in addition to the ingredients in Table 1 above, other minor ingredients, including various conventional refining aids, such as SO₃ and the like may also be included in the base glass. In certain embodiments, for example, glass herein may be made from batch raw materials silica sand, soda ash, dolomite, limestone, with the use of sulfate salts such as salt cake (Na₂SO₄) and/or Epsom salt (MgSO₄×7H₂O) and/or gypsum (e.g., about a 1:1 combination of any) as refining agents. In certain example embodiments, soda-lime-silica based glasses herein include by weight from about 10-15% Na₂O and from about 6-12% CaO. Moreover, from about 0.15 to 7% MgO, more preferably from about 1 to 7% MgO, is provided in the glass in certain example embodiments.

In certain example embodiments of this invention, the glass of substrate 1 is soda-lime-silica based (see base glass above) and is based on low iron raw materials such that the glass has a total iron (Fe₂O₃) content, in terms of wt. %, of no more than about 0.05%. In certain example embodiments, the glass has a total iron (Fe₂O₃) content of from about 0.010 to 0.045%, more preferably from about 0.010 to 0.035%, and most preferably from about 0.010 to 0.029%. This low iron content may result from the use of low-iron raw materials in making the glass, or alternatively may be added in certain example instances. Moreover, in certain example embodiments of this invention, the glass is extremely oxidized so as to have no or very little ferrous (Fe²⁺; FeO). In certain example embodiments of this invention, the glass has a % FeO of no more than about 0.0038%, more preferably no more than about 0.0030%, even more preferably no more than about 0.0015%, more preferably no more than about 0.0010%. This low % FeO, in combination with other features, permits the glass to have a higher % UV transmission, and thus a higher % TS transmission, in combination with neutral color and high visible transmission, which are beneficial in solar cell applications. However, more iron than that listed above may be used in the glass 1 in alternative embodiments of this invention.

In certain example non-limiting embodiments, there is no or very little cerium oxide in the glass. Cerium oxide is a UV absorber, and thus prevents UV from being transmitted through the glass. Thus, cerium oxide is not desired in certain solar cell embodiments of this invention. Accordingly, in certain example embodiments of this invention, the glass has no more than about 0.01% cerium oxide, more preferably no more than about 0.001% cerium oxide, still more preferably no more than about 0.0005% cerium oxide, and most preferably 0% cerium oxide. However, in alternative embodiments of this invention, it is possible to use a small amount of cerium oxide. For example and without limitation, in certain example embodiments of this invention, the glass contains, from about 0 to 0.2% cerium oxide, more preferably from about 0 to 0.1% cerium oxide, and possibly from about 0.001 to 0.09% cerium oxide. As with all material percentages herein, these amounts are in terms of wt. %. The term cerium oxide as used herein includes Ce₂O₃, CeO₂, or the like. In certain example instances, glasses including cerium oxide herein may be used in applications such as greenhouse glazings where UV protection is desired.

In certain example embodiments of this invention, the colorant portion is substantially free of other colorants (other than potentially trace amounts). However, it should be appreciated that amounts of other materials (e.g., refining aids, melting aids, colorants and/or impurities) may be present in the glass in certain other embodiments of this invention without taking away from the purpose(s) and/or goal(s) of the instant invention. For instance, in certain example embodiments of this invention, the glass composition is substantially free of, or free of, one, two, three, four or all of: erbium oxide, nickel oxide, cobalt oxide, neodymium oxide, chromium oxide, and selenium. The phrase “substantially free” means no more than 2 ppm, more preferably no more than 1 ppm, and possibly as low as 0 ppm of the element or material. It is noted that small amounts of titanium oxide may be included in certain instances.

Glass 1 according to certain example embodiments of this invention achieves a neutral or substantially clear color, high visible transmission, high IR transmission, high UV transmission, and high total solar (TS) transmission. In certain embodiments, resulting glasses according to certain example embodiments of this invention may be characterized by one or more of the following transmissive optical, composition, or color characteristics (for the optics, an example non-limiting reference thickness of about 4 mm is used). Note that Lta is visible transmission %. It is noted that in the table below the L*, a* and b* color values are determined per Ill. D65, 10 degree Obs.

TABLE 2
CHARACTERISTICS OF EXAMPLE EMBODIMENTS

| Characteristic | General | More Preferred | Most Preferred |
|---|---|---|---|
| Lta (Lt D65): | >=85% | >=91% | >=91.5% |
| % TS (ISO 9050): | >=90% | >=91% | >=91.5% |
| % IR | >=80% | >=85% | >=90% (or |
| | | | >=91%) |
| % UV (300-400 nm): | >=80% | >=84% | >=85% (or 86%) |
| total iron (Fe₂O₃): | <=0.05% | 0.010-0.045% | 0.010-0.035% |
| % FeO (wt. %): | <=0.0038% | <=0.0030% | <=0.0015% (or |
| | | | 0.0010%) |
| Glass Redox: | <=0.12 | <=0.09 | <=0.08 or 0.06 |
| Batch Redox: | +12 to +30 | +15 to +30 | +20 to +30 |
| SO₃ | >=0.25 | 0.29-0.50 | >=0.30 (or |
| | | | >=0.31) |
| L* (Ill. D65, 10 deg.): | 90-99 | 94-99 | 95-98 |
| a* (Ill. D65, 10 deg.): | −1.0 to +1.0 | −0.5 to +0.5 | −0.25 to 0.0 |
| b* (Ill. D65, 10 deg.): | 0 to +1.5 | +0.1 to +0.8 | +0.2 to +0.6 |

The aforesaid characteristics of the glass substrate 1 are for the glass substrate alone, not the overall photovoltaic device.

As can be seen from Table 2 above, glasses for substrate 1 of certain embodiments of this invention achieve desired features of fairly clear color and/or high visible transmission, with slightly positive b* color in certain embodiments, while not requiring iron to be eliminated from the glass composition. Moreover, high % UV and high % TS values are also achieved, which is advantageous for solar cell applications in that more radiation is permitted through the glass substrate 1 so that it can be converted to current or voltage. This may be achieved through the provision of the unique material combinations described herein, and/or process features discussed herein. For purposes of example and without limitation, glasses described in any of commonly owned U.S. Ser. Nos. 11/049,292, 11/122,218 and/or 11/373,490 may be used for substrate 1 in different example embodiments of this invention. While these represent example glass that may be used for the substrate, it is of course possible to use other glass compositions for the substrate 1 in alternative embodiments of this invention.

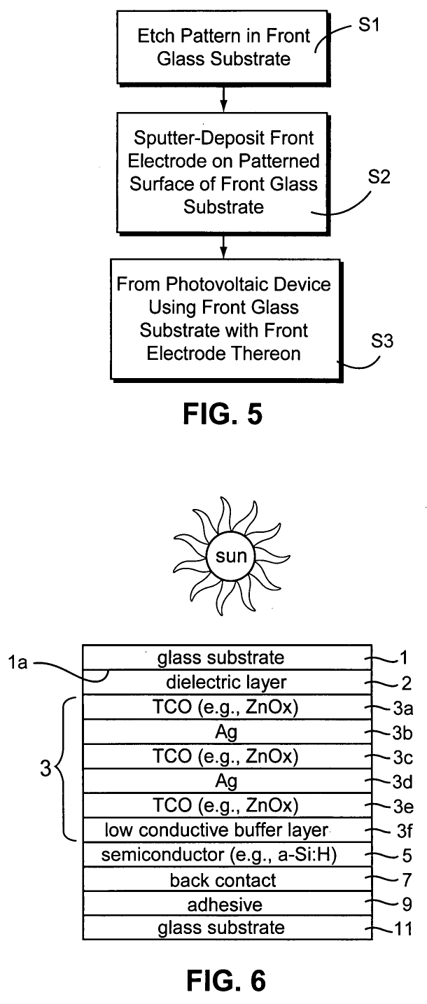

Referring to FIGS. 1 and 5, the front electrode structure of the device may be made as follows in certain example embodiments of this invention. Initially, the front glass substrate 1 of soda-lime silica based glass is provided. Then, one or both major surfaces of the front glass substrate 1 is etched (e.g., via HF etching using HF etchant or the like) or patterned via roller(s) or the like during glass manufacture in order to form a textured (or patterned) surface 1a (see step S1 in FIG. 5). As mentioned above, in order to achieve good haze properties, the soda-lime-silica based glass 1 has an etching ratio [(Al₂O₃/Na₂O)×(MgO/CaO)] of at least about 0.010, more preferably at least about 0.030, and most preferably at least about 0.035; and a ratio MgO/CaO of at least about 0.45 (more preferably at least about 0.47). These values have unexpectedly been found to provide for much better haze values of the front electrode 3 which is deposited on the textured surface 1a, compared to if these values in the glass are not met.

Then, the transparent conductive front electrode 3 is deposited, by sputtering one or more sputtering targets (e.g., a ZnAlOₓ ceramic target(s) or a ZnAl metal target(s)), on the textured surface 1a of the front glass substrate 1 (e.g., see step S2 in FIG. 5). The sputtering may be performed at approximately room temperature, optionally in a vacuum, using rotating magnetron sputtering targets in certain example instances. Alternatively, the electrode 3 may be sputter-deposited at elevated temperatures (e.g., from about 20-350 degrees C., possibly from about 100-250 degrees C.) in order to improve its crystallinity. The use of sputtering (e.g., DC, MF and/or RF type sputtering) to form the conductive electrode 3 is advantageous in that it permits the electrode (single or multi-layered) 3 to be deposited in a conformal manner so that both major surfaces of the electrode 3 are shaped in a manner similar to that of the textured surface 1a of the glass substrate 1 on which the electrode 3 has been deposited. Thereafter, in certain example embodiments, the semiconductor film 5 (and optionally the optional back contact 7) may be formed on the substrate 1 and electrode 3 via any suitable technique (e.g., CVD or the like), and then the rear substrate 11 may be laminated to the front electrode 1 via adhesive film 9 to form the photovoltaic device as shown in FIG. 1 (e.g., see step S3 in FIG. 5). The back contact 7 may or may not be conformal to/with the electrode 3, because the semiconductor 5 may or may not be planarizing in different example embodiments of this invention.

The active semiconductor region or film 5 may include one or more layers, and may be of any suitable material. For example, the active semiconductor film 5 of one type of single junction amorphous silicon (a-Si) photovoltaic device includes three semiconductor layers, namely a p-layer, an n-layer and an i-layer. The p-type a-Si layer of the semiconductor film 5 may be the uppermost portion of the semiconductor film 5 in certain example embodiments of this invention; and the i-layer is typically located between the p and n-type layers. These amorphous silicon based layers of film 5 may be of hydrogenated amorphous silicon in certain instances, but may also be of or include hydrogenated amorphous silicon carbon or hydrogenated amorphous silicon germanium, hydrogenated microcrystalline silicon, or other suitable material(s) in certain example embodiments of this invention. It is possible for the active region 5 to be of a double-junction or triple-junction type in alternative embodiments of this invention. CdTe and/or CdS may also be used for semiconductor film 5 in alternative embodiments of this invention.

Optional back contact or electrode 7 may be of any suitable electrically conductive material. For example and without limitation, the back contact or electrode 7 may be of a TCO and/or a metal in certain instances. Example TCO materials for use as back contact or electrode 7 include indium zinc oxide, indium-tin-oxide (ITO), tin oxide, and/or zinc oxide which may be doped with aluminum (which may or may not be doped with silver). The TCO of the back contact 7 may be of the single layer type or a multi-layer type in different instances. Moreover, the back contact 7 may include both a TCO portion and a metal portion in certain instances. For example, in an example multi-layer embodiment, the TCO portion of the back contact 7 may include a layer of a material such as indium zinc oxide (which may or may not be doped with aluminum or the like), indium-tin-oxide (ITO), tin oxide, and/or zinc oxide closest to the active region 5, and the back contact may include another conductive and possibly reflective layer of a material such as silver, molybdenum, platinum, steel, iron, niobium, titanium, chromium, bismuth, antimony, or aluminum further from the active region 5 and closer to the substrate 11. The metal portion may be closer to substrate 11 compared to the TCO portion of the back contact 7.

The photovoltaic module may be encapsulated or partially covered with an encapsulating material such as encapsulant 9 in certain example embodiments. An example encapsulant or adhesive for layer 9 is EVA or PVB. However, other materials such as Tedlar type plastic, Nuvasil type plastic, Tefzel type plastic or the like may instead be used for layer 9 in different instances.

FIG. 6 is a cross sectional view of a photovoltaic device according to another example embodiment of this invention. The FIG. 6 embodiment is the same as the FIG. 1 (and FIG. 5) embodiment discussed above, except that (i) the front electrode 3 includes multiple layers 3a-3f in the FIG. 6 embodiment, and (ii) dielectric layer 2 may optionally be present in the FIG. 6 embodiment (and the FIG. 1 embodiment). Referring to FIG. 6, multilayer front electrode 3 may include from the front glass substrate 1 moving toward semiconductor film 5, first TCO layer 3a, first conductive substantially metallic layer 3b, second TCO layer 3c, optional second conductive substantially metallic layer 3d, optional third TCO layer 3e, and optional buffer layer 3f. Optionally, layer 3a may be a dielectric layer (e.g., silicon oxide, silicon nitride, silicon oxynitride, etc.) instead of a TCO in certain example instances and serve as a seed layer for the layer 3b. This multilayer film makes up the front electrode 3 in certain example embodiments of this invention. Of course, it is possible for certain layers of electrode 3 to be removed in certain alternative embodiments of this invention (e.g., one or more of layers 3a, 3c, 3d and/or 3e may be removed), and it is also possible for additional layers to be provided in the multilayer electrode 3. Front electrode 3 may be continuous across all or a substantial portion of glass substrate 1, or alternatively may be patterned into a desired design (e.g., stripes), in different example embodiments of this invention. Each of layers/films 1-3 is substantially transparent in certain example embodiments of this invention. First and/or second conductive substantially metallic layers 3b and 3d may be of or based on any suitable material such as silver, gold, or the like. The highly conductive nature of these substantially metallic layers 3b and/or 3d permits the conductivity of the overall electrode 3 to be increased. In certain example embodiments of this invention, the multilayer electrode 3 has a sheet resistance of less than or equal to about 15 ohms/square, more preferably less than or equal to about 12 or 9 ohms/square, and even more preferably less than or equal to about 6 ohms/square. The increased conductivity (same as reduced sheet resistance) increases the overall photovoltaic module output power, by reducing resistive losses in the lateral direction in which current flows to be collected at the edge of cell segments. It is noted that first and second conductive substantially metallic layers 3b and 3d (as well as the other layers of the electrode 3) are thin enough so as to be substantially transparent to visible light. In certain example embodiments of this invention, first and/or second conductive substantially metallic layers 3b and/or 3d are each from about 3 to 12 nm thick, more preferably from about 5 to 10 nm thick, and most preferably from about 5 to 8 nm thick. In embodiments where one of the layers 3b or 3d is not used, then the remaining conductive substantially metallic layer may be from about 3 to 18 nm thick, more preferably from about 5 to 12 nm thick, and most preferably from about 6 to 11 nm thick in certain example embodiments of this invention. These thicknesses are desirable in that they permit the layers 3b and/or 3d to be substantially transparent to visible radiation which is permitted to reach the semiconductor 5 to be transformed by the photovoltaic device into electrical energy. The highly conductive layers 3b and 3d attribute to the overall conductivity of the electrode 3 more than the TCO layer(s); this allows for expansion of the process window(s) of the TCO layer(s) which has a limited window area to achieve both high conductivity and transparency.

Still referring to FIG. 6, first, second, and/or third TCO layers 3a, 3c and 3e, respectively, may be of any suitable TCO material including but not limited to conducive forms of zinc oxide (which may or may not be doped with Al or the like), tin oxide (which may or may not be doped with Sb or the like), indium-tin-oxide, indium zinc oxide (which may or may not be doped with silver), or the like. These layers are typically substoichiometric so as to render them conductive as is known in the art. For example, these layers are made of material(s) which gives them a sheet resistance of no more than about 100 ohms/square, more preferably no more than about 30 ohms/square (more preferably no more than about 25, and most preferably no more than about 20 ohms/square) when at a non-limiting reference thickness of about 400 nm. In certain example embodiments, the electrode 3 or TCO layer(s) may have a resistivity of 1000 ohm-cm or less, more preferably about 750 or 500 ohm-cm or less (the resistivity may be higher than usual given that Ag may be used for lateral conduction in the plane of the film). One or more of these layers may be doped with other materials such as nitrogen, fluorine, aluminum or the like in certain example instances, so long as they remain conductive and substantially transparent to visible light. In certain example embodiments of this invention, TCO layers 3c and/or 3e are thicker than layer 3a (e.g., at least about 5 nm, more preferably at least about 10, and most preferably at least about 20 or 30 nm thicker). In certain example embodiments of this invention, TCO layer 3a is from about 3 to 80 nm thick, more preferably from about 5-30 nm thick, with an example thickness being about 10 nm. Optional layer 3a is provided mainly as a seeding layer for layer 3b and/or for antireflection purposes, and its conductivity is not as important as that of layers 3b-3e. In certain example embodiments of this invention, TCO layer 3c is from about 20 to 150 nm thick, more preferably from about 40 to 120 nm thick, with an example thickness being about 74-75 nm. In certain example embodiments of this invention, TCO layer 3e is from about 20 to 180 nm thick, more preferably from about 40 to 130 nm thick, with an example thickness being about 94 or 115 nm. In certain example embodiments, part of layer 3e, e.g., from about 1-25 nm or 5-25 nm thick portion, at the interface between layers 3e and 5 may be replaced with a low conductivity high refractive index (n) film 3f such as titanium oxide to enhance transmission of light as well as to reduce back diffusion of generated electrical carriers; in this way performance may be further improved.

The alternating nature of the TCO layers 3a, 3c and/or 3e, and the conductive substantially metallic layers 3b and/or 3d (or alternatively of only 3a, 3b and 3c, or alternatively of only 3b and 3c as another example), is also advantageous in that it also one, two, three, or all of the following advantages to be realized: (a) reduced sheet resistance (Rₛ) of the overall electrode 3 and thus increased conductivity and improved overall photovoltaic module output power; (b) reduced reflection and increased transmission of light in the visible region of from about 450-700 nm (and/or 450-600 nm) by the front electrode 3 which leads to increased photovoltaic module output power; (c) reduced total thickness of the front electrode coating 3 which can reduce fabrication costs and/or time; and/or (d) an improved or enlarged process window in forming the TCO layer(s) because of the reduced impact of the TCO's conductivity on the overall electric properties of the module given the presence of the highly conductive substantially metallic layer(s).

With reference to FIGS. 2-4 below, it will be explained how in certain example embodiments of this invention a single or multi-layered front electrode 3 can be designed in such a way that the maximum transmission is tailored to the quantum efficiency (QE) of the intended photovoltaic device and the light source spectrum. Then, this front electrode can be fabricated using a magnetron sputtering technique on pre-etched or pre-patterned glass 1. Due to the conformal characteristics of magnetron sputtering, multiple or single layered optical coatings for electrode 3 can be fabricated while preserving or substantially preserving the textured shape 1a of the substrate 1 in the major surface of the electrode closest to the semiconductor film 5. In this way, the device output can be optimized through both improved light transmission and increased light path. The examples below each had more than 80% transmission (or at least 85%) into the semiconductor film 5 in part or all of the wavelength range of from about 450-600 nm and/or 450-700 nm, where AM1.5 has the strongest intensity (see FIGS. 2-4).

In Example 1 (see FIG. 2), the predicted transmission spectrum impinging into the amorphous silicon semiconductor film 5 from a three layered front electrode 3 was determined. The three layered front electrode 3 in this example included, on the textured surface 1a (measured haze of about 8.5%) of glass substrate 1 moving from the 3 mm glass 1 toward the semiconductor 5, a 47 nm thick TCO layer 3a of zinc oxide doped with aluminum, a 8 nm thick layer 3b of silver, and a 106 nm thick TCO layer 3c of zinc oxide doped with aluminum. The textured surface 1a of the glass substrate 1, and both major surfaces of the electrode 3, had peaks and valleys defined therein with inclined portions interconnecting the peaks and valleys. This three layered electrode 3 was sputter deposited on the pre-etched textured surface 1a of a soda-lime-silica based glass substrate 1. The measured haze was about 8.1% and the measured sheet resistance (Rₛ) of the electrode was 8.9 ohms/square, which are suitable for amorphous and microcrystal silicon single or tandem cell applications. The visible transmission in the graph in FIG. 2 is indicative of the percent of light from the source which made its way through the glass substrate 1 and electrode 3 and impinged upon the a-Si semiconductor film 5. FIG. 2 illustrates that the coating was designed so that its transmission was tailored to the quantum efficiency (QE) and light source spectrum (AM1.5). In particular, FIG. 2 shows that the front electrode structure, including electrode 3 and its textured surface 4a and layered make-up and the textured nature of substrate 1, was designed so that (a) its maximum transmission area occurs in the area under a peak area of the quantum efficiency (QE) curve of the photovoltaic device, (b) its maximum transmission occurs in the area under a peak area of the light source spectrum (e.g., AM1.5) (note that AM1.5 refers to air mass 1.5 which represents the AM1.5 photon flux spectrum that may be used to calculate device output power), and (c) its transmission into the semiconductor absorption film (a-Si, uc-Si, or the like) 5 is at least 80% (more preferably at least 85%, or even at least 87% or 88%) in part of, all of, or a substantial part of the wavelength range of from about 450-600 nm and/or 450-700 nm. These characteristics are advantageous for purposes of improving the efficiency of the photovoltaic device as explained herein.

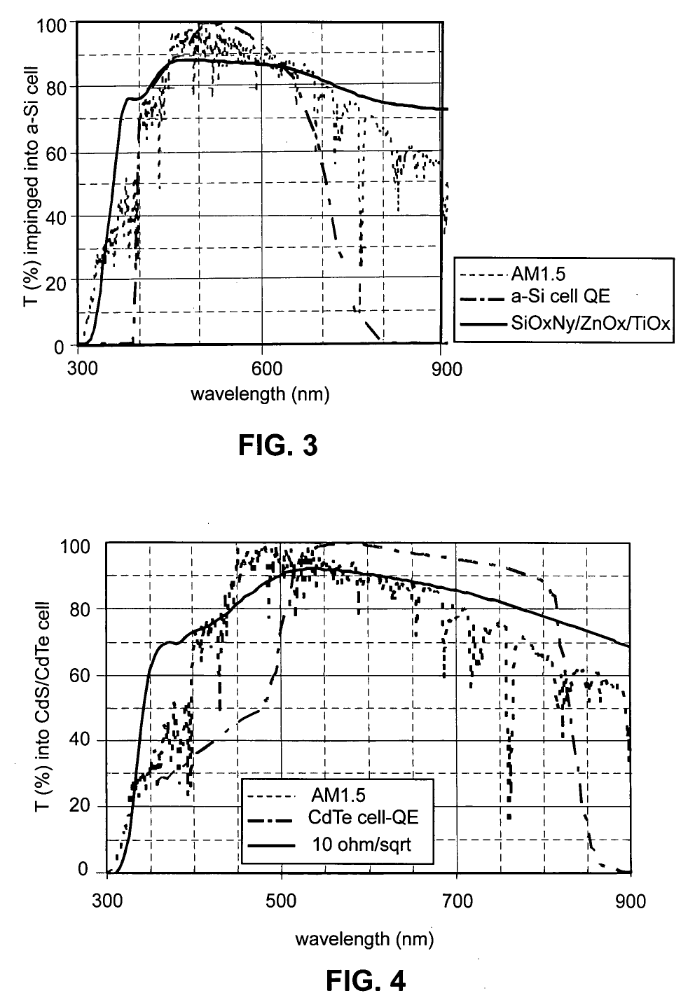

In Example 2 (see FIG. 3), the predicted transmission spectrum impinging into the amorphous silicon (a-Si) semiconductor film 5 from a different type of front electrode 3 was determined. In Example 2 there was formed on the textured surface 1a of 3 mm glass substrate 1 moving from the glass 1 toward the semiconductor 5, a 77 nm thick dielectric layer 3a of silicon oxynitride, a 350 nm thick TCO layer 3c of zinc oxide doped with aluminum, and a 46 nm thick buffer layer 3e of titanium oxide (which may or may not be doped with niobium or the like). This three layered electrode 3 was sputter deposited on the pre-etched textured surface 1a of a soda-lime-silica based glass substrate 1. The predicted haze was about 9% and the sheet resistance (Rₛ) of the electrode was about 15 ohms/square, which are suitable for amorphous and microcrystal silicon single or tandem cell applications. The visible transmission in the graph in FIG. 3 is indicative of the percent of light from the source which made its way through the glass substrate 1 and electrode 3 and impinged upon the a-Si semiconductor film 5. FIG. 3 illustrates that the coating was designed so that its transmission was tailored to the quantum efficiency (QE) and light source spectrum (AM1.5). In particular, FIG. 3 shows that the front electrode structure, including electrode 3 and its textured surface and layered make-up and the textured nature of substrate 1, was designed so that (a) its maximum transmission area occurs in the area under a peak area of the quantum efficiency (QE) curve of the photovoltaic device, (b) its maximum transmission area occurs in the area under a peak area of the light source spectrum (e.g., AM1.5), and (c) its transmission into the semiconductor absorption film 5 is at least 80% (more preferably at least 85%, or even at least 87% or 88%) in part of, all of, or a substantial part of the wavelength range of from about 450-600 nm and/or 450 or 500-700 nm. These characteristics are advantageous for purposes of improving the efficiency of the photovoltaic device as explained herein.

In Example 3 (see FIG. 4), the predicted transmission spectrum impinging into the CdS/CdTe inclusive semiconductor film 5 from a different type of front electrode 3 was determined. In Example 3 there was formed on the textured surface 1a of 3 mm glass substrate 1 moving from the glass 1 toward the semiconductor 5, a triple layered dielectric layer 2 of 15 nm thick silicon nitride followed by a 16 nm thick layer of titanium dioxide and then a 10 nm thick layer of zinc oxide doped with aluminum, a 9 nm thick layer 3b of silver, and a 140 nm thick low conductive buffer layer 3f of tin oxide. This multi-layered electrode 3 was sputter deposited on the pre-etched textured surface 1a of a soda-lime-silica based glass substrate 1. The haze was about 2.7% and the sheet resistance (Rₛ) of the electrode was about 10 ohms/square, which are suitable for CdTe thin film solar cell applications. In FIG. 4, the solid line is predicted transmission spectra into the CdS/CdTe photovoltaic device. The transmission in the graph in FIG. 4 is indicative of the percent of light from the source which made its way through the glass substrate 1 and electrode 3 and impinged upon the CdS/CdTe semiconductor film 5. FIG. 4 illustrates that the coating 3 was designed so that its transmission was tailored to the quantum efficiency (QE) and light source spectrum (AM1.5). In particular, FIG. 4 shows that the front electrode structure, including electrode 3 and its textured surface 4a and layered make-up and the textured nature of substrate 1, was designed so that (a) its maximum transmission area occurs in the area under a peak area of the quantum efficiency (QE) curve of the photovoltaic device, (b) its maximum transmission area occurs in the area under a peak area of the light source spectrum (e.g., AM1.5), and (c) its transmission is at least 80% (more preferably at least 85%, or even at least 87% or 88%) in part of, all of, or a substantial part of the wavelength range of from about 450-600 nm and/or 450-750 nm. Note that the QE curve for the CdTe photovoltaic device is shifted relative to those of the a-Si photovoltaic devices in FIGS. 2-3, and the characteristics of the electrode structure were modified accordingly to fit the shifted QE curve. These characteristics are advantageous for purposes of improving the efficiency of the photovoltaic device as explained herein.

In certain example embodiments of this invention, it is possible for the glass substrate 1 to have both a patterned side (e.g., patterned via rollers or the like, to form a prismatic side for instance) and a matte finish side. The matter finish side may be formed via acid etching techniques so that the matte finish side of the glass substrate is an acid etched side of the glass. The electrode 3 may be formed on the matte or acid-etched side of the glass substrate 1 which textured to some extent. Moreover, in certain example embodiments of this invention, the glass substrate 1 has a haze value of from about 8-20%, more preferably from about 12-18%.

While the invention has been described in connection with what is presently considered to be the most practical and preferred embodiment, it is to be understood that the invention is not to be limited to the disclosed embodiment, but on the contrary, is intended to cover various modifications and equivalent arrangements included within the spirit and scope of the appended claims.

1. A method of making a photovoltaic device, the method comprising:
providing a soda-lime-silica based glass substrate which comprises from about 67-75% SiO₂, from about 10-20% Na₂O, from about 5-15% CaO, from about 0.1 to 8% MgO, and from about 0.1 to 5% Al₂O₃;
etching at least one major surface of the glass substrate to form a textured surface of the glass substrate, wherein an etching ratio ((Al₂O₃/Na₂O)* (MgO/CaO)) of the glass substrate is at least about 0.010, and a ratio MgO/CaO in the glass substrate is at least about 0.45;
sputter-depositing a substantially transparent and electrically conductive front electrode on the textured surface of the glass substrate; and
using the front electrode formed on the textured surface of the glass substrate at a light incident side of a photovoltaic device.

2. The method of claim 1, wherein the etching ratio ((Al₂O₃/Na₂O)* (MgO/CaO)) is at least about 0.030.

3. The method of claim 1, wherein the etching ratio ((Al₂O₃/Na₂O)* (MgO/CaO)) is at least about 0.035.

4. The method of claim 1, wherein the ratio MgO/CaO is at least about 0.47, and wherein the etching comprises etching the glass substrate using at least hydrofluoric acid.

5. The method of claim 1, wherein said sputter-depositing comprises sputter-depositing the front electrode on the textured surface of the glass substrate in a substantially conformal manner so that both major surfaces of the front electrode are textured in a manner similar to the textured surface of the glass substrate.

6. The method of claim 1, wherein said front electrode comprises zinc aluminum oxide, and wherein the etching comprises etching the glass substrate using at least hydrofluoric acid.

7. The method of claim 1, wherein said front electrode consists essentially of a single layer comprising zinc aluminum oxide.

8. The method of claim 1, further comprising determining a quantum efficiency (QE) curve for a photovoltaic device, and forming the front electrode in a manner so that a maximum transmission area of the front electrode is located under a peak area of the QE curve for the photovoltaic device.

9. The method of claim 8, further comprising forming the front electrode in a manner so that the maximum transmission area of the front electrode is located under a peak area of a combination of QE and a light source spectrum expected to be used to power the photovoltaic device.

10. The method of claim 9, wherein the light source spectrum is AM1.5.

11. The method of claim 8, further comprising forming the front electrode in a manner so that a transmission of the front electrode and the glass substrate taken together, into a semiconductor film of the photovoltaic device, is at least 80% in at least a substantial part of a wavelength range of from about 450-600 nm.

12. The method of claim 11, further comprising forming the front electrode in a manner so that the transmission of the front electrode and the glass substrate taken together is at least 85% in at least a substantial part of a wavelength range of from about 450-600 nm.

13. The method of claim 12, further comprising forming the front electrode in a manner so that the transmission of the front electrode and the glass substrate taken together is at least 87% in at least a substantial part of a wavelength range of from about 450-600 nm.

14. The method of claim 1, wherein the front electrode is multi-layered and comprises at least one layer that is conductive and substantially transparent.

15. The method of claim 14, wherein the transparent front electrode comprises, moving away from at least the glass substrate toward a semiconductor film of the photovoltaic device, at least a first substantially transparent conductive substantially metallic layer comprising silver and/or gold, and a first transparent conductive oxide (TCO) layer.

16. The method of claim 1, wherein the front electrode comprises first and second spaced apart layers comprising silver.

17. The method of claim 1, wherein the front electrode comprises zinc oxide and/or zinc aluminum oxide and is from about 100 to 1,000 nm thick.

18. A method of making a photovoltaic device, the method comprising:
providing a soda-lime-silica based glass substrate which comprises from about 67-75% SiO₂, from about 10-20% Na₂O, from about 5-15% CaO, from about 0.1 to 8% MgO, and from about 0.1 to 5% Al₂O₃;
etching at least one major surface of the glass substrate to form a textured surface of the glass substrate, wherein (a) an etching ratio ((Al₂O₃/Na₂O)* (MgO/CaO)) of the glass substrate is at least about 0.010, and/or (b) a ratio MgO/CaO in the glass substrate is at least about 0.45;
sputter-depositing a substantially transparent and electrically conductive front electrode on the textured surface of the glass substrate; and
using the front electrode formed on the textured surface of the glass substrate at a light incident side of a photovoltaic device.

19. The method of claim 18, wherein the etching ratio ((Al₂O₃/Na₂O)* (MgO/CaO)) is at least about 0.030, and the ratio MgO/CaO in the glass is at least about 0.45.

20. The method of claim 18, wherein the etching ratio ((Al₂O₃/Na₂O)* (MgO/CaO)) is at least about 0.035, and the ratio MgO/CaO in the glass is at least about 0.45, and wherein the etching comprises etching the glass substrate using at least hydrofluoric acid.

21. The method of claim 18, wherein the etching ratio ((Al₂O₃/Na₂O)* (MgO/CaO)) is at least about 0.030, and the ratio MgO/CaO is at least about 0.47.

22. The method of claim 18, wherein said sputter-depositing comprises sputter-depositing the front electrode on the textured surface of the glass substrate in a substantially conformal manner so that both major surfaces of the front electrode are textured in a manner similar to the textured surface of the glass substrate.

23. The method of claim 18, wherein said front electrode comprises zinc aluminum oxide.

24. A photovoltaic device comprising:
a soda-lime-silica based front glass substrate which comprises from about 67-75% SiO₂, from about 10-20% Na₂O, from about 5-15% CaO, from about 0.1 to 8% MgO, and from about 0.1 to 5% Al₂O₃;
a semiconductor film;
a substantially transparent conductive front electrode provided between at least the front glass substrate and the semiconductor film; and
wherein a ratio ((Al₂O₃/Na₂O)*(MgO/CaO)) of a composition of the glass substrate is at least about 0.010, and a ratio MgO/CaO of the composition of the glass substrate is at least about 0.45.

25. The photovoltaic device of claim 24, wherein the ratio ((Al₂O₃/Na₂O)* (MgO/CaO)) is at least about 0.030.

26. The photovoltaic device of claim 24, wherein the ratio ((Al₂O₃/Na₂O)* (MgO/CaO)) is at least about 0.035.

27. The photovoltaic device of claim 24, wherein the ratio MgO/CaO is at least about 0.47.

28. The photovoltaic device of claim 24, wherein a transmission of the front electrode and the front glass substrate taken together, into the semiconductor film, is at least 80% in at least a substantial part of a wavelength range of from about 450-600 nm.

29. The photovoltaic device of claim 28, wherein the transmission of the front electrode and the front glass substrate taken together is at least 85% in at least a substantial part of a wavelength range of from about 450-600 μm.

30. The photovoltaic device of claim 24, wherein the glass substrate has a haze value of from about 8-20%.

31. The photovoltaic device of claim 24, wherein the glass substrate has a total iron (Fe₂O₃) content, in terms of wt. %, of no more than about 0.05%.

32. The method of claim 1, wherein the glass substrate has a total iron (Fe₂O₃) content, in terms of wt. %, of no more than about 0.05%.
